(19) United States
(12) Patent Application Publication
(10) Pub. No.: US 2005/0263764 A1
(43) Pub. Date: Dec. 1, 2005

(54) CMOS imaging device having an improved fill factor

(76) Inventors: Ki-hong Kim, Yongin-si (KR); Soo-cheol Lee, Seoul (KR)

Correspondence Address: LEE, STERBA, & MORSE, P.C., SUITE 2000, 1101 WILSON BOULEVARD, ARLINGTON, VA, 22209, US

(21) Appl. No.: 11/090,159

(22) Filed: Mar. 28, 2005

(30) Foreign Application Priority Data
Jun. 1, 2004 (KR) 04-39624

(51) Int. Cl. H01L 27/108

(52) U.S. Cl. 257/69; 257/72

(57) ABSTRACT

A CMOS imaging device includes a semiconductor substrate having an isolation region and an active region, a plurality of gate electrodes formed on respective predetermined portions of the active region, and a plurality of gate electrode contacts that transmit external signals to each of the plurality of gate electrodes, wherein at least one, and up to all, of the plurality of gate electrode contacts overlap the active region.

### BACKGROUND OF THE INVENTION

1. Field of the Invention

The present invention relates to an imaging device. More particularly, the present invention relates to a complementary metal oxide semiconductor (CMOS) imaging device having an improved fill factor.

2. Description of the Related Art

Generally, an imaging device converts an optical image into electrical signals. Typical imaging devices include charge coupled devices (CCD) and CMOS imaging devices (sensor). A CCD includes a plurality of MOS capacitors, and is operated by transferring charge (carriers) to the MOS. The CMOS imaging device is composed of a plurality of unit pixels that contain photo diodes, and the unit pixels are operated by a control circuit and signal processing.

The CCD has some drawbacks, such as a complicated driving method, high power consumption, complicated manufacturing process, and difficult integration, since a signal processing circuit cannot be integrated in the CCD chip. On the other hand, the CMOS imaging device can be manufactured by conventional CMOS techniques, and therefore, current research focuses on easily manufacturing a CMOS image sensor.

A conventional CMOS image sensor includes a pixel region that senses images and a CMOS logic region that controls output signals of the pixel region. The pixel region can be composed of a photo diode and a MOS transistor, and the CMOS logic region can be composed of a plurality of CMOS transistors.

FIG. 1 illustrates a plan view of a conventional CMOS imaging device having a general pixel region and logic region. Referring to FIG. 1, a conventional CMOS imaging device 10 includes a pixel array region 12 and a CMOS logic region 15 on a circuit substrate 11.

The pixel array region 12 includes a plurality of unit pixels 12a arranged in a matrix. As shown in FIG. 2, the unit pixel 12a includes a transfer transistor 124 that transfers charge generated by a photo diode 122, a reset transistor 126 that periodically resets a floating diffusion region (FD) that stores charge transferred from the transfer transistor 124, and a source follower 128 that buffers signals according to the charge stored in the FD. The source follower 128 can be two MOS transistors connected in series.

FIG. 3 illustrates a plan view of a general pixel array region of a CMOS imaging device for the unit pixel 12a of FIG. 1. Referring to FIG. 3, a plurality of active regions 20 are defined by forming an isolation layer 25 to define photo diode regions and transistor regions on a predetermined portion of a semiconductor substrate (not shown).

A plurality of the active regions 20 can be disposed in a matrix spaced apart from each other by a predetermined distance. The active region 20 includes a photo diode region 20a on which a photo diode will be formed and a transistor region 20b on which a transfer transistor, a reset transistor, and a source follower will be formed. The photo diode region 20a is formed to occupy almost all of a unit pixel region, e.g., to a rectangular plate shape. The photo diode region 20a is preferably formed as wide as possible so that the maximum amount of light can be received. The transistor region 20b is formed by extending from a predetermined portion of the photo diode and can be formed in a line shape. The transistor region 20b is preferably formed as narrow as possible.

Gate electrodes 24, 26, 28, and 29 of the transistor are disposed on the active regions 20. The gate electrode 24 of the transfer transistor 124 is disposed on a boundary surface between the photo diode region 20a and the transistor region 20b, and the gate electrode 26 of the reset transistor 126 and gate electrodes 28 and 29 of transistors M1 and R1 that constitute the source follower 128 are disposed on the transistor region 20b spaced apart at a predetermined distance.

A photo diode 30, a floating diffusion region (FD), and a connecting region 32 of transistors are formed by injecting a dopant into the active regions 20a and 20b on both sides the gate electrodes 24, 26, 28, and 29.

Contacts 40 and 42 are formed for transmitting external signals to the gate electrodes 24, 26, 28, and 29, to the floating diffusion region, and to the connecting region 32. The contacts 40 of the gate electrodes 24, 26, 28, and 29 are formed on extended gate electrodes 24, 26, 28, and 29 toward outer regions of the active regions 20, i.e., above the isolation layer 25, and the contacts 42 of the floating diffusion region (FD) and the connecting region 32 are formed on the floating diffusion region and the connecting region 32, respectively.

However, as described above, each of the active regions 20 must be separated from each other by the size of the gate contact 40, since the gate contacts 40 of the gate electrodes 24, 26, 28, and 29 are formed on the isolation film 25, which is an outer region of the active regions 20. In other words, the active regions 20 must be separated from each other by a distance that can prevent a short circuit between the agte contacts 40 and the active regions 20.

In the unit pixels defined as above, the area of the active regions 20, i.e., the area of the photo diode region 20a, decreases relatively, since the active regions 20 must be separated from each other by a predetermined distance.

If the area of the photo diode region 20a is reduced, the fill factor, i.e., the area occupied by the photo diode in the unit pixel, is reduced, thereby reducing the dynamic range of the CMOS imaging device.

### SUMMARY OF THE INVENTION

The present invention is therefore directed to a CMOS imaging device, which substantially overcomes one or more of the problems due to the limitations and disadvantages of the related art.

It is therefore a feature of an embodiment of the present invention to provide a CMOS imaging device having an improved fill factor by increasing the area of a photo diode region.

It is another feature of an embodiment of the present invention to form contacts, preferably all of the gate electrode contacts, of a CMOS imaging device on active regions.

At least one of the above and other features and advantages of the present invention may be realized by providing a CMOS imaging device including a semiconductor substrate having an isolation region and an active region, a plurality of gate electrodes formed on respective predetermined portions of the active region, and a plurality of gate electrode contacts that transmit external signals to each of the plurality of gate electrodes, at least one of the plurality of gate electrode contacts overlapping the active region.

The active region may include a photo diode region having a shape of reduced pixel region and a transistor region extended from a predetermined portion of the photo diode region. The plurality of gate electrodes may include a gate electrode of a transfer transistor, a gate electrode of a reset transistor, and a gate electrode of transistors that constitute a source follower. The gate electrodes may be formed on the transistor region. The gate electrode of the transfer transistor may be formed on a boundary between the transistor region and the photo diode region. All of the plurality of gate electrode contacts may overlap the active region.

At least one of above and other features and advantages of the present invention may be realized by providing CMOS imaging device, including a semiconductor substrate on which a plurality of pixel regions are defined, an active region formed in each of the plurality of pixel regions, the active region including a photo diode region and a transistor region, at least one gate electrode formed on the transistor region, a photo diode, a floating diffusion region, and a connecting region formed on the active region on both sides of the at least one gate electrode, a first contact that transfers electrical signals to the at least one gate electrode, and a second contact that transfers electrical signals to the floating diffusion region and a selected connecting region, wherein the first contact overlaps the active region.

The photo diode region may have a rectangular shape occupying a substantial majority of the plurality of the pixel regions, and the transistor region may have a linear shape extending toward a predetermined portion of the photo diode region. The transistor region may include a transfer transistor, a reset transistor, and transistors that constitute a source follower, and the at least one gate electrode may include a gate electrode of the transfer transistor, a gate electrode of the reset transistor, and gate electrodes of the transistors that constitute the source follower. First contacts for corresponding gate electrodes may overlap the active region. The gate electrode of the transfer transistor may be formed on a boundary between the transistor region and the photo diode region.

At least one of the above and other features and advantages of the present invention may be realized by providing a CMOS imaging device having a photo diode that generates charge in response to external light, a floating diffusion region that stores charge generated by the photo diode, a transfer transistor that transfers charge to the floating diffusion region, a reset transistor that periodically resets the floating diffusion region, and a source follower that buffers signals according to the stored charge in the floating diffusion region, the CMOS imaging device including an active region on which the photo diode, the transfer transistor, the reset transistor, and the source follower are formed, a gate electrode for each of the transfer transistor, the reset transistor, and the source follower, and a contact for transmitting external signals to each gate electrode, at least one contact being formed on the active region.

All contacts may be formed on the active region. A first portion of the active region on which the photodiode is formed may have a rectangular shape and a second portion of the active region on which the transfer transistor, the reset transistor, and the source follower are formed, may extend from a predetermined portion of the first portion. The gate electrode of the transfer transistor may be formed on a boundary between the first and second portions.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a plan view of a conventional CMOS imaging device having a general pixel region and logic region;

FIG. 2 is a circuit diagram of a unit pixel region of FIG. 1;

FIG. 3 illustrates a plan view of a unit pixel of FIG. 1; and

FIG. 4 illustrates a plan view of a unit pixel region according to an embodiment of the present invention.

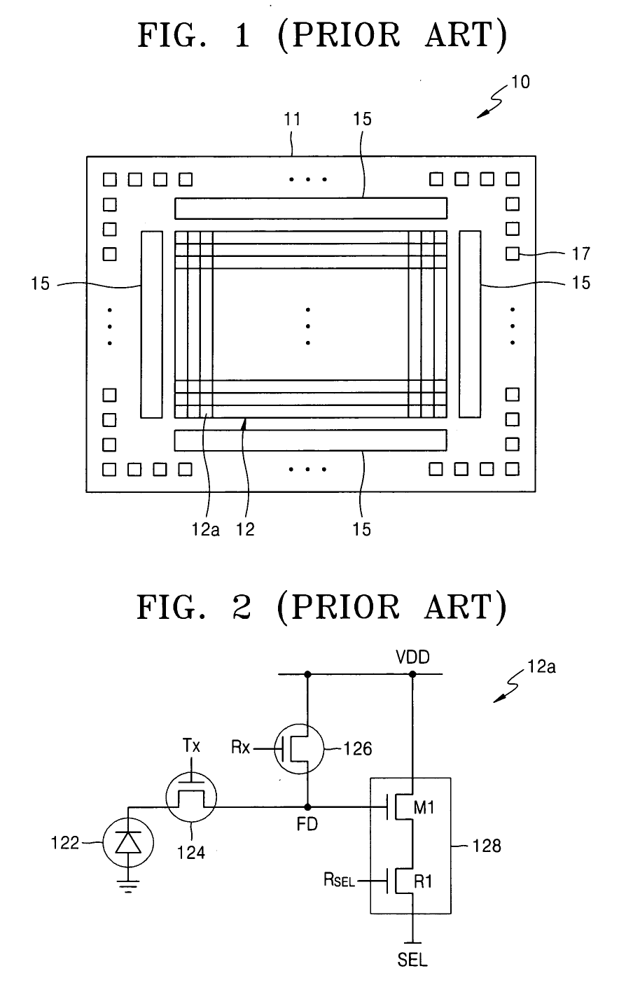

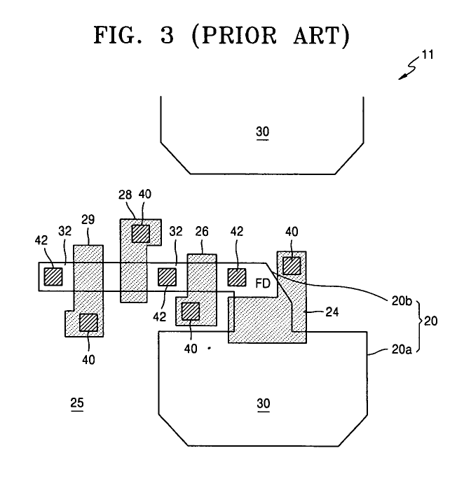

### DETAILED DESCRIPTION OF THE INVENTION

Korean Patent Application No. 2004-39642, filed on Jun. 1, 2004, in the Korean Intellectual Property Office, and entitled: “CMOS Imaging Device Improved Fill Factor,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of elements and regions are exaggerated for clarity of illustration. Like reference numerals refer to like elements throughout.

An aspect of the present invention is to form contacts, preferably all of the gate electrode contacts, of a CMOS imaging device on active regions. Thus, the area of the active regions can be increased up to the area of the contacts, since the contacts do not need to be located on an isolation layer formed between active regions, by locating the gate electrode contacts that transfer signals to the gate electrodes, on the active regions.

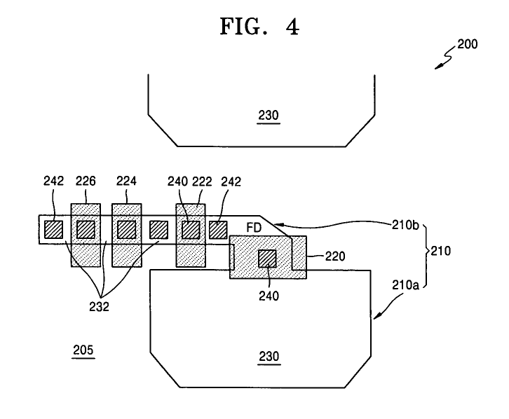

The CMOS imaging device designed as above will now be described in detail with reference to FIG. 4.

Referring to FIG. 4, a plurality of active regions 210 are defined by forming an isolation film 205 on a predetermined portion of a semiconductor substrate 200. The active regions 210 can be formed in a matrix by forming one active region 210 per a plurality of pixels. Each of the active regions 210 includes a photo diode region 210a, on which a photo diode will be formed, and a transistor region 210b, on which a transfer transistor, a reset transistor, and a source follower will be formed. The photo diode region 210a may be formed to occupy the majority of the region confined by unit pixels, e.g., to a rectangular plate shape of a reduced unit pixel. The transistor region 210b may have a line shape extending from a predetermined portion of a surface of the photo diode region 210a.

Gate electrodes 220, 222, 224, and 226 of a transistor are disposed on the active regions 210. Preferably, the gate electrode 220 of the transfer transistor 124 is disposed on the boundary between the photo diode region 210a and the transistor region 210b, and the gate electrode 222 of the reset transistor 126 and the gate electrode 224 and 226 of transistors M1 and R1 that constitute the source follower 128 are disposed on the transistor region 210b at a predetermined spacing.

A photo diode 230, a floating diffusion region (FD), and connecting regions 232 of transistors are formed by implanting a dopant into the active regions 210a and 210b on both sides the gate electrodes 220, 222, 224, and 226.

Contacts 240 and 242 are formed for transmitting external signals to the gate electrodes 220, 222, 224, and 226, to the FD, and to the connecting region 32. In the present embodiment, the contacts 240 of the gate electrodes 220, 222, 224, and 226 overlap the active regions 210. Also, the contacts 242 of the floating diffusion region and the connecting region 232 are respectively formed on the floating diffusion region and the connecting region 232.

In the present embodiment, the area of the contacts 240 does not need to be considered when defining the gap between the active regions 210, since all of the contacts 240 are disposed on the gate electrode 220, 222, 224, and 226. Accordingly, the area of the active regions 210, i.e., the area of the photo diode region 210a can be increased, since the gap between the active regions 210 can be reduced.

For example, a CMOS imaging device of a super-extended graphics array (SXGA) (1280×1024) resolution has a pixel size of approximately 3.8 μm×3.8 μm and a contact area of 0.22 μm×0.22 μm. Therefore, if the contact 240 of the gate electrode is formed on the active regions 210, the gap between the active regions 210 can be reduced by more than 0.22 μm. Accordingly, the fill factor can be increased by at least 3%.

Also, a CMOS imaging device of video graphics array (VGA) (640×480) resolution has a pixel size of approximately 5.6 μm×5.6 μm and a contact area of 0.4 μm×0.4 μm. Therefore, if the contact 240 of the gate electrode is formed on the active regions 210, the gap between the active regions 210 can be reduced by more than 0.4 μm. Accordingly, the fill factor can be increased by at least 4%.

As described above, according to an embodiment of the present invention, contacts that transmit external signals to a gate electrode are formed on an active region. Accordingly, the area of the active region, that is, the area of the photo diode region, can be increased, since the gap between the active regions can be reduced by at least the area of the contact.

The increase in the area of the photo diode region improves the fill factor of the CMOS imaging device, thereby increasing its dynamic range.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A complementary metal oxide semiconductor (CMOS) imaging device, comprising:
a semiconductor substrate having an isolation region and an active region;
a plurality of gate electrodes formed on respective predetermined portions of the active region; and
a plurality of gate electrode contacts that transmit external signals to each of the plurality of gate electrodes, at least one of the plurality of gate electrode contacts overlapping the active region.

2. The CMOS imaging device as claimed in claim 1, wherein the active region comprises a photo diode region having a shape of reduced pixel region and a transistor region extended from a predetermined portion of the photo diode region.

3. The CMOS imaging device as claimed in claim 2, wherein the plurality of gate electrodes comprises:
a gate electrode of a transfer transistor, a gate electrode of a reset transistor, and a gate electrode of transistors that constitute a source follower; and
the gate electrodes are formed on the transistor region.

4. The CMOS imaging device as claimed in claim 3, wherein the gate electrode of the transfer transistor is formed on a boundary between the transistor region and the photo diode region.

5. The CMOS imaging device as claimed in claim 1, wherein all of the plurality of gate electrode contacts overlap the active region.

6. A complementary metal oxide semiconductor (CMOS) imaging device, comprising:
a semiconductor substrate on which a plurality of pixel regions are defined;
an active region formed in each of the plurality of pixel regions, the active region including a photo diode region and a transistor region;
at least one gate electrode formed on the transistor region;
a photo diode, a floating diffusion region, and a connecting region formed on the active region on both sides of the at least one gate electrode;
a first contact that transfers electrical signals to the at least one gate electrode; and
a second contact that transfers electrical signals to the floating diffusion region and a selected connecting region,
wherein the first contact overlaps the active region.

7. The CMOS imaging device as claimed in claim 6, wherein the photo diode region has a rectangular shape occupying a substantial majority of the plurality of the pixel regions, and the transistor region has a linear shape extending toward a predetermined portion of the photo diode region.

8. The CMOS imaging device as claimed in claim 6, wherein the transistor region comprises a transfer transistor, a reset transistor, and transistors that constitute a source follower, and the at least one gate electrode comprises a gate electrode of the transfer transistor, a gate electrode of the reset transistor, and gate electrodes of the transistors that constitute the source follower.

9. The CMOS imaging device as claimed in claim 8, wherein first contacts for corresponding gate electrodes overlap the active region.

10. The CMOS imaging device as claimed in claim 8, wherein the gate electrode of the transfer transistor is formed on a boundary between the transistor region and the photo diode region.

11. A complementary metal oxide semiconductor (CMOS) imaging device including a photo diode that generates charge in response to external light, a floating diffusion region that stores charge generated by the photo diode, a transfer transistor that transfers charge to the floating diffusion region, a reset transistor that periodically resets the floating diffusion region, and a source follower that buffers signals according to the stored charge in the floating diffusion region, the CMOS imaging device comprising:
an active region on which the photo diode, the transfer transistor, the reset transistor, and the source follower are formed;
a gate electrode for each of the transfer transistor, the reset transistor, and the source follower; and
a contact for transmitting external signals to each gate electrode, at least one contact being formed on the active region.

12. The CMOS imaging device as claimed in claim 11, wherein all contacts are formed on the active region.

13. The CMOS imaging device as claimed in claim 11, wherein a first portion of the active region on which the photodiode is formed has a rectangular shape and a second portion of the active region on which the transfer transistor, the reset transistor, and the source follower are formed extends from a predetermined portion of the first portion.

14. The CMOS imaging device as claimed in claim 13, wherein the gate electrode of the transfer transistor is formed on a boundary between the first and second portions.
